(19) United States
(12) Patent Application Publication
(10) Pub. No.: US 2011/0062571 A1
(43) Pub. Date: Mar. 17, 2011

(54) OPTICAL DEVICE, INTEGRATED CIRCUIT DEVICE AND SYSTEM

(75) Inventor: Nedyalko Slavov, Zurich (CH)

(73) Assignee: ST-ERICSSON SA, Geneva (CH)

(21) Appl. No.: 12/558,413

(22) Filed: Sep. 11, 2009

(51) Int. Cl. H01L 23/58; H01L 21/50

(52) U.S. Cl. 257/680; 438/116; 257/E23.002; 257/E21.499

(57) ABSTRACT

An optical device for an integrated circuit device, includes a laminated substrate having a through-passage and a tubular frame in which an optical lens is mounted, the tubular frame having an end part inserted or integrated in the through-passage of the laminated substrate. A integrated circuit device includes an optical device and an integrated circuit die carried by the laminated substrate and having an active optical area placed in front of the optical lens.

### BACKGROUND

1. Technical Field

The present invention relates to the field of integrated circuit devices or packages and integrated circuit systems.

2. Description of the Related Art

A known integrated circuit system comprises a mounting plate, an integrated circuit die having an optical area mounting on the mounting plate and an annular support mounting on the mounting plate around the die and provided with an optical lens placed in front of the optical area.

### BRIEF SUMMARY

It is proposed an optical device for an integrated circuit device, which can include a laminated substrate having a through-passage and a tubular frame in which an optical lens is mounted, the tubular frame having an end part inserted or integrated in the through-passage of the laminated substrate.

The tubular frame can comprise a peripheral shoulder inserted or integrated in the laminated substrate.

The laminated substrate can comprise a core layer having a through-passage receiving the peripheral shoulder of the tubular frame and at least a side layer placed above a side of the core layer.

The laminated substrate can comprise a core layer having a through-passage receiving the peripheral shoulder of the tubular frame and side layers placed on each side of the core layer.

The laminated substrate can include an electrical connection network.

It is proposed an integrated circuit device, which can include an optical device and an integrated circuit die carried by the laminated substrate and having an active optical area placed in front of the optical lens.

The device can comprise an encapsulated means for encapsulating the integrated circuit die on a face of the substrate.

It is proposed an integrated circuit system, which can include an integrated circuit device and a mounting plate on which the integrated circuit device is mounted by means of connection balls placed between the laminated substrate and the mounting plate, the mounting plate having a through-passage through which the tubular frame extends.

It is proposed an integrated circuit system, which can include a mounting plate on which the integrated circuit device is mounted by means of connection balls placed between the laminated substrate and the mounting plate, the frame being placed at the opposite side of the mounting plate.

It is proposed a process for manufacturing an optical device comprising a tubular frame and an optical lens, which can include making an annular groove inside the tubular frame, heating the tubular frame for obtaining a radial dilatation thereof, placing the optical lens in the tubular frame in a position in which the peripheral edge of the lens is in front of the groove while the tubular frame is dilated and cooling the tubular frame for obtaining a radial retraction thereof permitting the peripheral edge of the optical lens to be insert in the annular groove. The process can also include introducing an end peripheral shoulder of the tubular frame in a cavity of a core layer of a substrate having a build-up layer on a face of the core layer and extending on a face of the peripheral shoulder, and placing a die on the substrate, this die having an optical area in front of the optical lens.

### BRIEF DESCRIPTION OF THE SEVERAL VIEWS OF THE DRAWINGS

Other advantages and features will become apparent by studying integrated circuit systems, described by way of non-limited examples and illustrated by the appended drawings in which:

FIG. 1 represents a cross section of an integrated circuit system;

FIG. 2 represents a cross section of another integrated circuit system;

FIG. 3 represents a cross section of an intermediate step of fabrication of an optical device of FIG. 1;

FIG. 4 represents a cross section of another intermediate step of fabrication of an optical device of FIG. 1;

FIG. 5 represents a cross section of an intermediate step of fabrication of an integrated circuit device of FIG. 1;

FIG. 6 represents a cross section of another intermediate step of fabrication of an integrated circuit device of FIG. 1; and

FIG. 7 represents a cross section of another intermediate step of fabrication of an integrated circuit device of FIG. 1.

### DETAILED DESCRIPTION

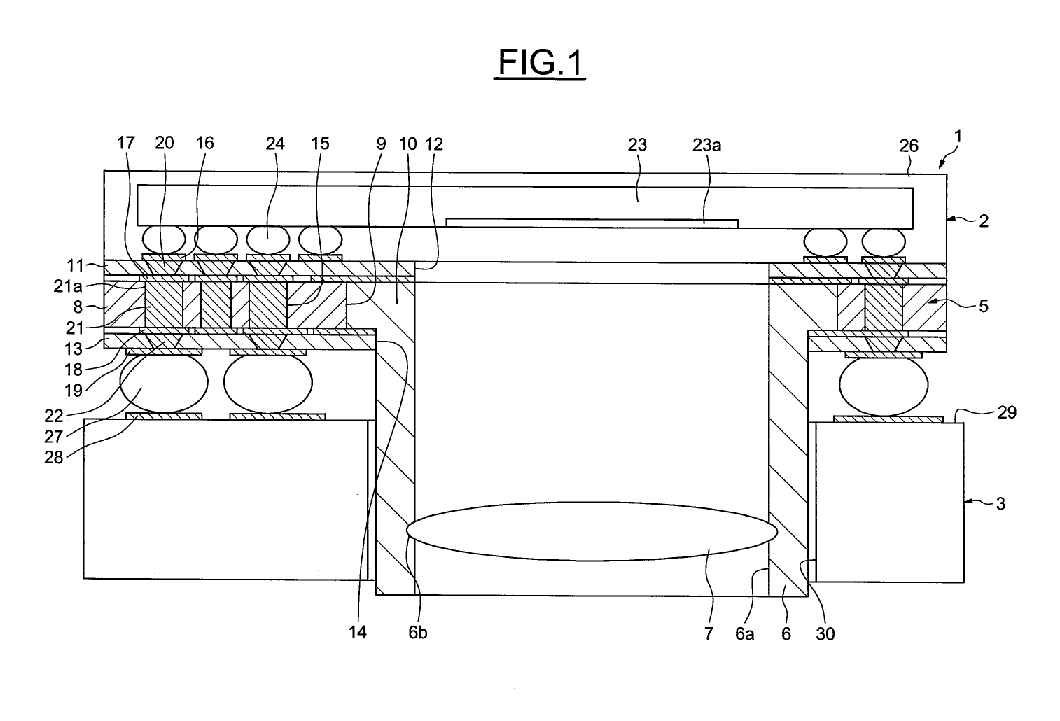

Referring to FIG. 1, it can be seen that an integrated circuit system 1 is represented, comprising an optical integrated circuit device or package 2 and a connection mounting plate 3.

The integrated circuit package 2 includes an optical device 4 comprising a laminated substrate 5 and a tubular frame 6 placed perpendicularly to the laminated substrate 5 and supporting an optical lens 7 in its passage 6a.

The laminated substrate 5 comprises a dielectric core layer 8 having a through-passage 9.

The tubular frame 6 is provided with a peripheral end shoulder 10 which is inserted in the passage 9.

The laminated substrate 5 comprises a first dielectric build-up layer 11 placed above a side of the core layer 8 and above the radial end of the tubular frame adjacent to the shoulder 10, this first build-up layer 11 having a through-passage 12 corresponding to the passage 6a of the frame 6.

The thickness of the shoulder 10 can be substantially equal to the thickness of the core layer 8.

The laminated substrate 5 comprises also a second dielectric build-up layer 13 placed above another side of the core layer 8 and the other side of the shoulder 10, this second build-up layer 11 having a through-passage 14 traversed by the tubular frame 6.

The laminated substrate 5 includes an electrical connection network 15 which comprises a connection pattern 16 formed on the external face of the build-up layer 11, a connection pattern 17 formed between the core layer 8 and the build-up layer 11, a connection pattern 18 formed between the core layer 8 and the build-up layer 13, and an external connection pattern 19 formed on the external face of the build-up layer 13.

The electrical connection network 15 comprises further electrical vias 20 crossing the build-up layer 11 for connecting the connection pattern 16 and the connection pattern 17, electrical vias 21 crossing passages 21a of the core layer 8 for connecting the connection pattern 17 and the connection pattern 18, and electrical vias 22 crossing the build-up layer 13 for connecting the connection pattern 18 and the connection pattern 19.

The integrated circuit package 2 includes further an integrated circuit die 23, opposite to the tubular frame 6 and mounted by intermediate electrical connection balls 24 located between connection points of a face of the die 23 and the connection pattern 16. The integrated circuit die 23 includes an active optical area 25 placed in correspondence to the passage 6a of the tubular frame 6 and in consequence in front of the optical lens 7.

The integrated circuit package 2 includes also an encapsulating block 26 which encapsulates the die 23 and the connection balls 24 above the external face of the side layer 11.

As an example, the package 2 can be manufactured according to the following steps.

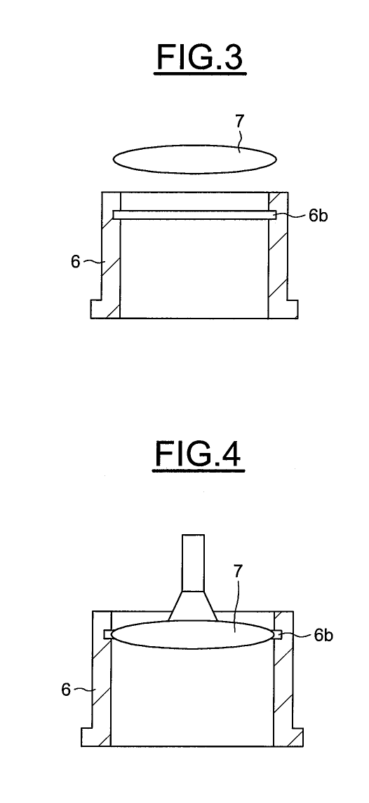

For fabricating the tubular frame 6 provided with the lens 7, a groove 6b is made inner a metal tubular frame (FIG. 3). This frame 6 is heated for obtaining a radial dilatation thereof and an optical lens 7 is placed in the tubular frame in a position in which the peripheral edge of the lens 7 is in front of the groove while the tubular frame is dilated (FIG. 4). After this, the tubular frame is cooled for obtaining a radial retraction thereof permitting the peripheral edge of the lens 7 to be inserted in the annular groove 6b.

Having a core layer plate, through-holes 21a are realized and metal vias 21 are realized. Metal layers are formed on the sides of the core layer plate and are etching for obtaining connection patterns 17 and 18. Having a side build-up layer 13 providing with a metal connection pattern 19 and metal vias 22, this side layer 13 is linked to the corresponding side of the core layer plate. After this, a hole 9 is realized through the core layer plate and a hole 14 is realized through the side layer 13.

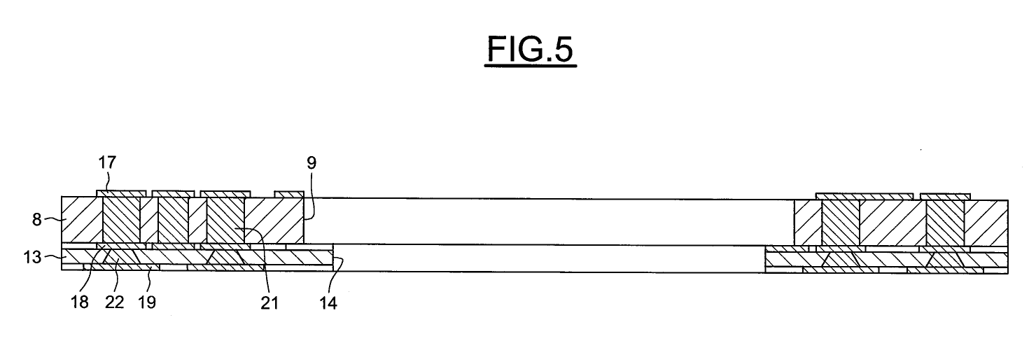

The structure obtained at the end of the above step is illustrated on FIG. 5.

After this, the tubular frame 6 is introduced through the holes 9 and 14 up to insert the shoulder 10 thereof in the hole 9 of the core layer 8, eventually with interposition of glue, in contact with the side layer.

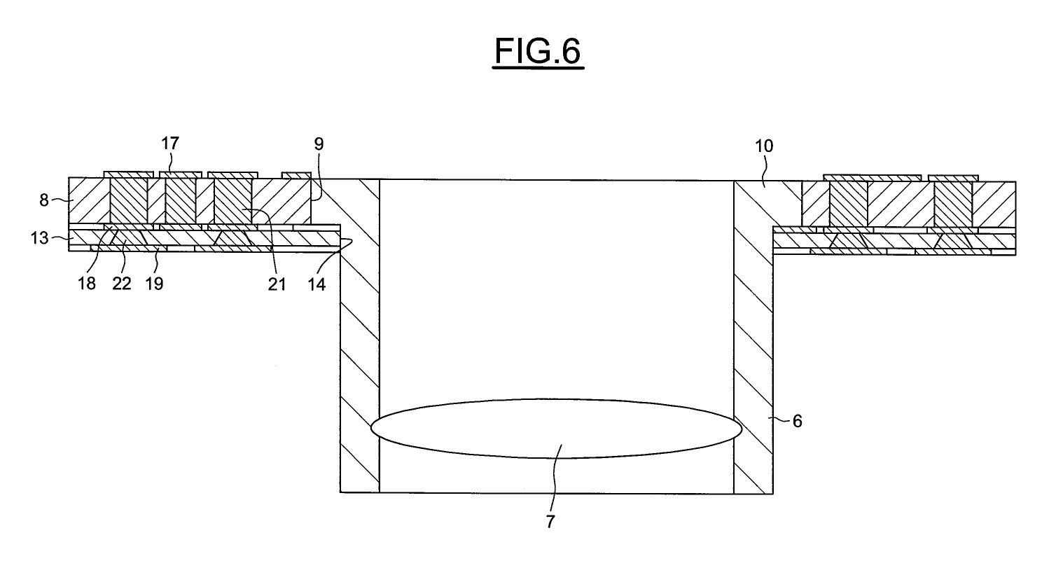

The structure obtained at the end of the above step is illustrated on FIG. 6.

After this, a side build-up layer 11 with a metal connection pattern 16 and metal vias 20 is formed on the corresponding side of the core layer 8, this side build-up layer 11 having the through-hole 12.

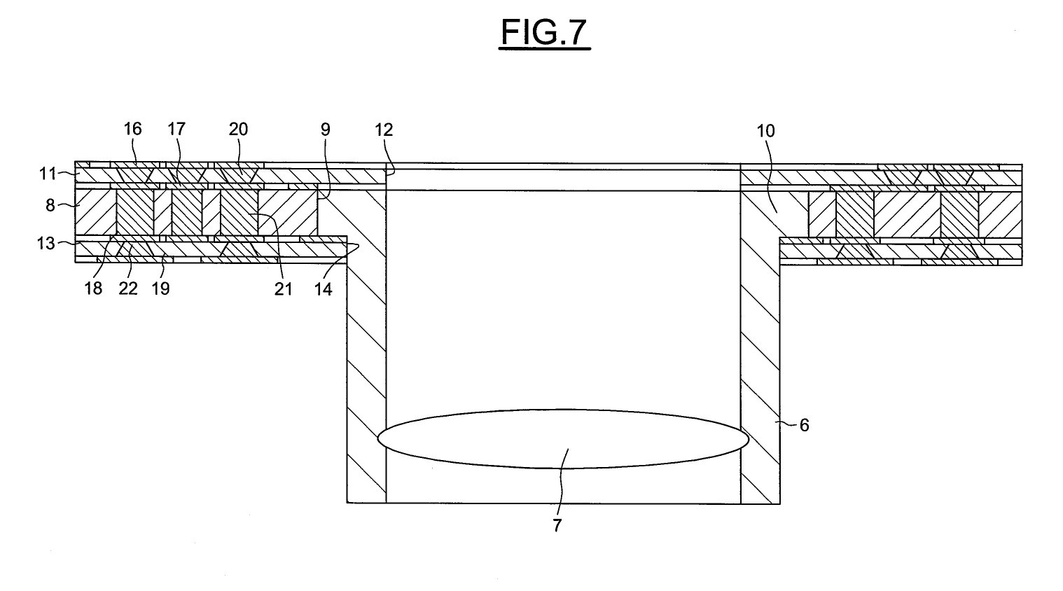

An optical device 4 obtained at the end of the above step is illustrated on FIG. 7.

Consequently, the end part of the tubular frame 6 is inserted in the laminated substrate 5, by the means of the peripheral shoulder 10 integrated in the through-hole 9 of the core layer 8 and between the side layers 11 and 13, around the through-holes 12 and 14 thereof, of the laminated substrate 5.

After this, an integrated circuit die 23 is attached by means of connection solder balls 24, in a position in which the sensitive optical area 24 is turned towards the lens 7, and an encapsulated block 26 is formed for example by molding.

At the end of the above step, an integrated circuit package 2 is realized.

As illustrated on FIG. 1, the integrated circuit package 2 as above described can be carried by the connection mounting plate 3 by the intermediate of electrical connection solder balls 27 located between the connection pattern 19 and a printed-circuit pattern 28 formed on a face 29 of the mounting plate 3, the tubular frame 6 being engaged freely through a through-passage 30 of the mounting plate 3 and the die 23 being opposite to the mounting plate 3 with respect to the laminated substrate 5.

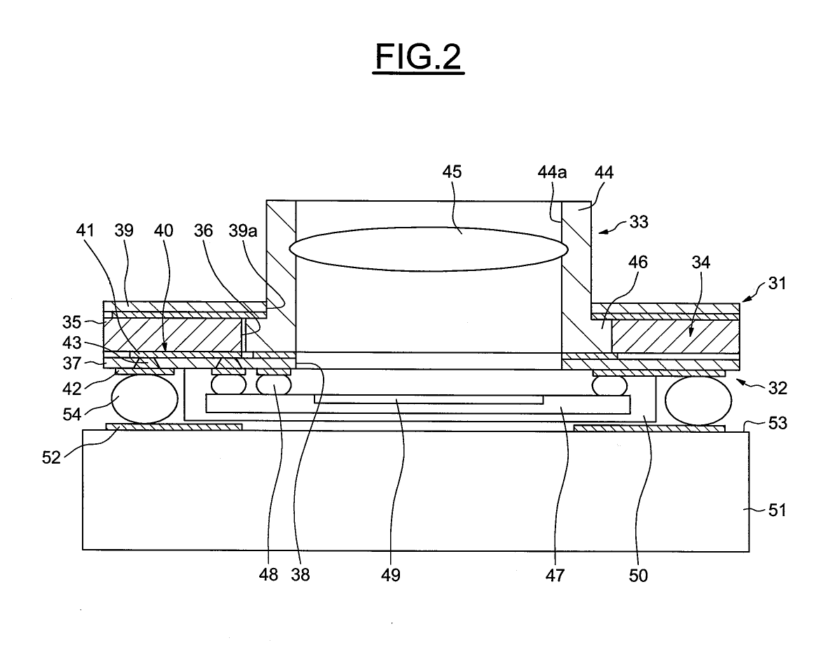

Referring now to FIG. 2, as another example, it can be seen that an integrated circuit system 31 is represented, comprising an integrated circuit device or package 32 including an optical device 33.

The optical device 33 differs from the optical device 4 by the fact that it includes a different laminated substrate 34.

The laminated substrate 34 comprises a dielectric core layer 35 having a through-passage 36, a side dielectric build-up layer 37 having a through-passage 38, corresponding to the build-up layer 11, and a simple dielectric layer 39 replacing the build-up layer 13 and having a through-passage 39a.

The laminated substrate 34 includes a metal electrical connection network 40 which comprises a connection pattern 41 formed between the core layer 35 and the build-up layer 37, a connection pattern 42 formed on the external side of the build-up layer 37 and vias 43 through the build-up layer 37 for connecting the connection pattern 41 and the connection pattern 42. A metal layer 44 is provided between the core layer 35 and the simple layer 39.

As in the previous example, a tubular frame 44 provided with an optical lens 45 extends perpendicularly to the laminated substrate 34 and has an end peripheral shoulder 46 which is integrated in the through-passage 36 of the core layer 35 and between the build-up layer 37 and the simple layer 39, this frame extending through the through-passage 39a of the simple layer 39.

The integrated circuit package 32 includes further an integrated circuit die 47, opposite to the tubular frame 44 and mounted by intermediate electrical connection balls 48 located between connection points of a face of the die 47 and certain points of the connection pattern 42. The integrated circuit die 47 includes an active optical area 49 placed in correspondence to the through-passage 44a of the tubular frame 44 and in consequence in front of the optical lens 45.

The integrated circuit package 32 includes also an encapsulating block 50 which encapsulates the die 47 and the connection solder balls 48 above the external face of the side build-up layer 37. The encapsulating block 50 is such that a peripheral portion of the connection pattern 42 is not covered.

The integrated circuit package 32 can be fabricated substantially as the package 2 of the previous example.

The integrated circuit system 31 includes further a mounting plate 51 providing with a printed-circuit pattern 52 on a face 53.

The integrated circuit package 32 is linked to the mounting plate 51 by the intermediate of connection solder balls 54 which are placed between the peripheral portion of the connection pattern 42 and the printed-circuit pattern 52, the tubular frame 44 extending opposite to the mounting plate 51 with respect to the laminated substrate and further the integrated circuit die 47 and the mounting plate 51 being placed at the same side with respect to the laminated substrate 34.

It results from the above description the following advantages.

The core layer 8 gives the principle resistance of the substrate 5.

The fixing end part of the frame 6 and 11 having eventually the shoulder 10 is inserted or integrated in a cavity of the substrate 5 formed in the passage 9 of the core layer 8 and eventually between the side layers 11 and 13.

Resulting from this integration, the frame 6 and the lens 7 carried thereby are perfectly positioned.

Although embodiments of the devices and systems of the present disclosure have been illustrated in the accompanying drawings and described in the foregoing detailed description, it will be understood that the invention is not limited to the embodiments disclosed, but is capable of numerous rearrangements, modifications and substitutions without departing from the spirit of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An optical device for an integrated circuit device, comprising:
a laminated substrate having a through-passage;
a tubular frame having an end part in the through-passage of the laminated substrate; and
an optical lens mounted in the tubular frame.

2. A device according to claim 1, in which the end part of the tubular frame comprises a peripheral shoulder in the laminated substrate.

3. A device according to claim 2, in which the laminated substrate comprises a core layer having a through-passage receiving the peripheral shoulder of the tubular frame and at least a side layer placed above a side of the core layer.

4. A device according to claim 2, in which the laminated substrate comprises a core layer having a through-passage receiving the peripheral shoulder of the tubular frame and side layers placed on respective sides of the core layer.

5. A device according to claim 1, in which the laminated substrate includes an electrical connection network.

6. An integrated circuit device, comprising:
an optical device that includes:
a laminated substrate having a through-passage;
a tubular frame having an end part in the through-passage of the laminated substrate; and
an optical lens mounted in the tubular frame; and
an integrated circuit die carried by the laminated substrate and having an active optical area placed in front of the optical lens.

7. A device according to claim 6, comprising an encapsulated means for encapsulating the integrated circuit die on a face of the substrate.

8. An integrated circuit system, comprising:
a integrated circuit device that includes:
an optical device that includes:
a laminated substrate having a through-passage;
a tubular frame having an end part inserted or integrated in the through-passage of the laminated substrate; and
an optical lens mounted in the tubular frame; and
an integrated circuit die carried by the laminated substrate and having an active optical area placed in front of the optical lens;
a mounting plate on which the integrated circuit device is mounted; and
connection balls configured to mount the integrated circuit device on the mounting plate, the connection balls being placed between the laminated substrate and the mounting plate.

9. An integrated circuit system according to claim 8, wherein the mounting plate has a through-passage through which the tubular frame extends.

10. A integrated circuit system according to claim 8, wherein the frame is placed an opposite side of the integrated circuit die with respect to the mounting plate.

11. A process, comprising:
manufacturing an optical device for an integrated circuit device, the manufacturing including:
forming a laminated structure having a through-passage;
forming tubular frame having an end part in the through-passage of the laminated substrate, and
mounting an optical lens in the tubular frame.

12. A process according to claim 11, wherein the mounting includes:
making an annular groove inside the tubular frame,
radially dilating the tubular frame by heating the tubular frame,
placing the optical lens in the tubular frame in a position in which a peripheral edge of the lens is in front of the annular groove while the tubular frame is dilated, and
radially retracting the tubular frame by cooling the tubular frame and permitting the peripheral edge of the optical lens to be inserted in the annular groove.

13. A process according to claim 12, further comprising:
introducing an end peripheral shoulder of the tubular frame in a cavity of a core layer of the laminated substrate, the laminated substrate having a build-up layer on a face of the core layer and extending on a face of the peripheral shoulder, and
placing a die on the substrate, the die having an optical area in front of the optical lens.
